(19) United States
(12) Patent Application Publication
(10) Pub. No.: US 2015/0162069 A1
(43) Pub. Date: Jun. 11, 2015

(54) INFORMATION PROCESSING TERMINAL AND POWER CONTROL METHOD

(71) Applicant: FUJITSU LIMITED, Kawasaki-shi (JP)

(72) Inventor: Koji MATSUSHIMA, San Jose, CA (US)

(21) Appl. No.: 14/562,506

(22) Filed: Dec. 5, 2014

(30) Foreign Application Priority Data
Dec. 10, 2013 (JP) 2013-255402

(51) Int. Cl. G11C 11/4074

(52) U.S. Cl. CPC G11C 11/4074

(57) ABSTRACT

An information processing terminal having a DRAM configured with a plurality of chips, the information processing terminal includes a memory, and a processor coupled to the memory, configured to monitor a temperature of each of the plurality of chips and, when the DRAM is transitioned to a standby mode, store data in a region of a chip with a low temperature among the plurality of chips and hold the data in the region alone.

### CROSS-REFERENCE TO RELATED APPLICATION

This application is based upon and claims the benefit of priority of the prior Japanese Patent Application No. 2013-255402, filed on Dec. 10, 2013, the entire contents of which are incorporated herein by reference.

### FIELD

The embodiments discussed herein are related to a technique of controlling power of a synchronous dynamic random access memory (SDRAM) configured with multiple chips, and the like.

### BACKGROUND

In an SDRAM which is mounted in an information processing terminal such as a mobile terminal, a memory capacity increases as the information processing terminal becomes more sophisticated and has higher performance. As the memory capacity increases, power to be consumed in the SDRAM also increases. In the information processing terminal, a ratio of standby power is large according to increased data amount in the SDRAM even in a so-called standby mode in which it is not operated.

Regarding such an SDRAM, it is known that an SDRAM transitions to a refresh mode in a standby mode to reduce power consumption.

It is known that a temperature sensor is provided to this SDRAM and an optimum refresh rate is set based on temperature information from the temperature sensor. These techniques are disclosed in, for example, Japanese Laid-open Patent Publication Nos. 2002-290547 and 2011-44215.

### SUMMARY

According to an aspect of the invention, an information processing terminal having a DRAM configured with a plurality of chips, the information processing terminal includes a memory, and a processor coupled to the memory, configured to monitor a temperature of each of the plurality of chips and, when the DRAM is transitioned to a standby mode, store data in a region of a chip with a low temperature among the plurality of chips and hold the data in the region alone.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a control unit and SDRAM of a mobile terminal according to a first embodiment;

FIG. 2 is a flowchart illustrating an exemplary power control processing procedure;

FIG. 3 is a diagram illustrating an exemplary mobile terminal according to a second embodiment;

FIG. 4 is a diagram illustrating an exemplary hardware of the terminal device;

FIG. 5 is a diagram illustrating an exemplary application processor and SDRAM of the terminal device;

FIG. 6 is a diagram illustrating an exemplary SDRAM chip;

FIG. 7A is a diagram illustrating functions of the application processor;

FIG. 7B is a diagram illustrating functions of the application processor;

FIG. 8 is a flowchart illustrating a processing procedure of SDRAM standby transition processing;

FIG. 9A is a diagram illustrating data allocation before and after the SDRAM standby;

FIG. 9B is a diagram illustrating data allocation before and after the SDRAM standby;

FIG. 10 is a flowchart illustrating an exemplary processing procedure of SDRAM power control;

FIG. 11 is a diagram illustrating an exemplary processing sequence of SDRAM power control;

FIG. 12 is a flowchart illustrating an exemplary procedure of chip determination processing;

FIG. 13 is a diagram illustrating data saving in the SDRAM standby;

FIG. 14A is a diagram illustrating data allocation before and after the SDRAM standby;

FIG. 14B is a diagram illustrating data allocation before and after the SDRAM standby;

FIG. 15A is a diagram illustrating another data allocation before and after the SDRAM standby;

FIG. 15B is a diagram illustrating another data allocation before and after the SDRAM standby;

FIG. 16A is a diagram illustrating still another data allocation before and after the SDRAM standby;

FIG. 16B is a diagram illustrating still another data allocation before and after the SDRAM standby;

FIG. 17 is a graph illustrating a correlation between standby power and temperature of the SDRAM;

FIG. 18 is another processing sequence of SDRAM power control according to another embodiment;

FIG. 19 is still another processing sequence of SDRAM power control according to another embodiment; and

FIG. 20A is a diagram illustrating a display example of the data allocation before and after the SDRAM standby.

FIG. 20B is a diagram illustrating a display example of the data allocation before and after the SDRAM standby.

### DESCRIPTION OF EMBODIMENTS

Standby power of an SDRAM depends on an amount of a memory capacity. Accordingly, if the memory capacity is reduced, the standby power may also be reduced. However, in a high-functioning and high-performance information processing terminal, it is impossible that a memory capacity of an SDRAM is reduced.

For this reason, used is such a partial refresh that, when the SDRAM transitions to a standby mode, stored data including programs is saved and regions of the memory to be refreshed are refreshed not in all regions but in partial regions. As for this partial refresh, even when a refresh rate is optimized based on temperature monitoring performed by a temperature sensor (for example, Japanese Laid-open Patent Publication No. 2011-44215), as the miniaturization of SDRAM chips is advanced, the temperature in relation to the standby power is affected. Moreover, the power consumption largely varies according to the temperature conditions, and as the temperature becomes higher, the standby power increases. In other words, there is such a problem that when the SDRAM chips are miniaturized, depending on the temperature, even when the refresh rate is optimized, the power consumption of the standby processing at a high temperature is impossible of being reduced.

Such a problem occurs not only in the SDRAM but also in a DRAM.

For this reason, with a view to such a problem, an object of the present disclosure is to save power when a DRAM is in a standby mode.

### First Embodiment

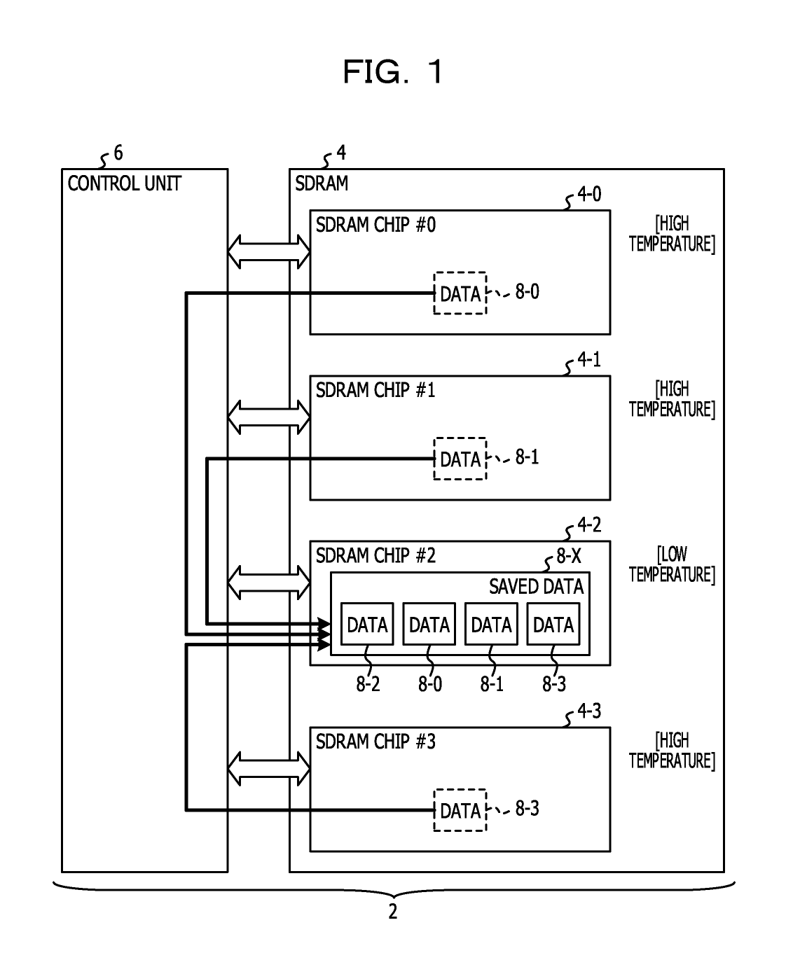

FIG. 1 illustrates a control unit and an SDRAM of a mobile terminal according to a first embodiment.

A mobile terminal 2 is an example of an information processing terminal of the present disclosure and may be an electronic device with a DRAM, such as a mobile telephone, a smart phone, a tablet terminal, a mobile personal computer (PC), or the like. The DRAM includes an SDRAM.

The mobile terminal 2 includes an SDRAM 4 and a control unit 6. The SDRAM 4 is an example DRAM of the present disclosure. This SDRAM 4 is provided with multiple SDRAM chips, for example, four pairs of SDRAM chips (hereinafter simply referred to as “chips”) 4-0, 4-1, 4-2, and 4-3. Data 8 is stored in regions of the chips 4-0, 4-1, 4-2, and 4-3 at random.

The control unit 6 controls reading and writing of the data 8 in the SDRAM. This control unit 6 includes a power control function. The power control function includes a temperature monitoring function and a data saving function. The temperature monitoring function monitors a memory temperature for each of the chips 4-0, 4-1, 4-2, and 4-3. The data saving function stores the data 8 in a region of the chip with a low temperature and holds data in the region alone just before the SDRAM 4 is transitioned to a standby mode.

In the foregoing configuration, the temperatures of the chips 4-0, 4-1, 4-2, and 4-3 are monitored. It is assumed as an example that the temperatures of the chips 4-0, 4-1, and 4-3 are high and the temperature of the chip 4-2 is low. As a result of monitoring the chip temperature by the control unit 6, when the SDRAM 4 is transitioned to a standby mode, the control unit 6 stores each piece of data 8-0, 8-1, and 8-3 of the chips 4-0, 4-1, and 4-3 with a high temperature in a region of the chip 4-2 with a low temperature and holds the data in the region alone. In this case, saved data 8-X in the chip 4-2 includes data 8-2 which has been in the chip 4-2 and the data 8-0, 8-1, and 8-3 which are saved.

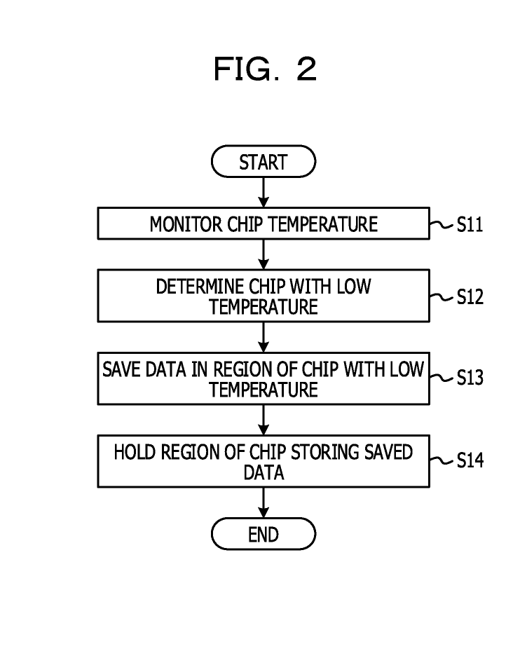

FIG. 2 illustrates a processing procedure of performing power saving processing on the SDRAM 4. The processing procedure is an example of a power control program or a power control method according to the present disclosure.

The processing procedure is executed by the control unit 6. The temperatures of the chips 4-0, 4-1, 4-2, and 4-3 at startup or in motion are monitored (step S11). For example, in this temperature monitoring, a chip with a low temperature is determined from temperature information of the chips 4-0, 4-1, 4-2, and 4-3 (step S12). When it is assumed that the temperatures of the chips 4-0, 4-1, and 4-3 are high and the temperature of the chip 4-2 is low, it is determined that the chip 4-2 is determined as the chip with a low temperature.

When the SDRAM 4 is transitioned to the standby mode, data is saved in a region with a low temperature (step S13). When the temperature of the chip 4-2 is low, the data is saved in the chip 4-2. In this case, when the SDRAM 4 is transitioned to the standby mode, data 8-0, 8-1, and 8-3 are saved in the region of the chip 4-2 with a low temperature (step S13). When existing data 8-2 exists in the chip 4-2, the data 8-0, 8-1, and 8-3 are stored together with the data 8-2 in the chip 4-2 as data 8-X.

Then, only the region in which the saved data is stored is held (step S14), the processing terminates. In this case, the saved data 8-X is stored in the chip 4-2 with a low temperature and only the region is held.

### Effects of the First Embodiment

(1) Since the data 8-0, 8-1, and 8-3 which are stored in the chips 4-0, 4-1, and 4-3 are saved and stored in the region with a low temperature, for example, the region of the chip 4-2, the standby power is suppressed and saving the power of the SDRAM 4 is achieved.

(2) Since the data 8-0, 8-1, 8-2, and 8-3 are saved just before the SDRAM 4 is transitioned to the standby mode, the stored data is usable until the transition to the standby mode, and thus the processing before the transition to the standby mode is not disturbed. Moreover, since the chip with a low temperature is determined by the temperature information just before the transition to the standby mode so as to save data, the data 8-0, 8-1, and 8-3 may be actually saved in the chip with a low temperature, for example, the chip 4-2. Accordingly, the power saving is secured.

(3) Even when an effect of the temperature increases along with the miniaturization of the chips 4-0, 4-1, 4-2, and 4-3, data is saved in a chip with a low temperature. Thus, the power consumption in standby may be suppressed.

(4) The power consumption is suppressed as described above, so that the power saving of the mobile terminal 2 is achieved and a life of battery may be prolonged.

### Second Embodiment

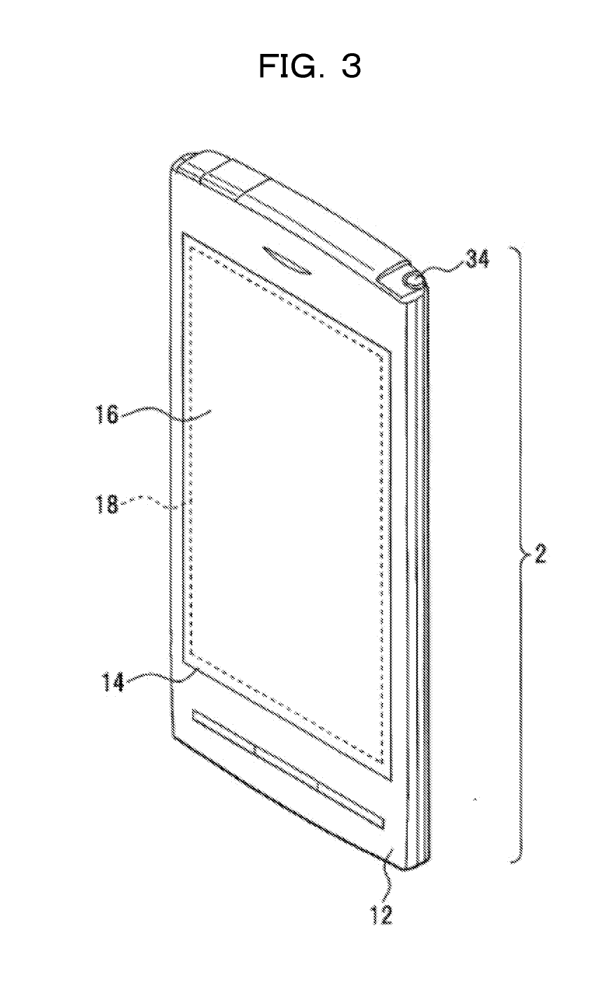

FIG. 3 illustrates an example mobile terminal according to a second embodiment. Same reference numerals are given to denote portions same as those of FIG. 1. This mobile terminal 2 is a smartphone, for example. The mobile terminal 2 includes a body portion 12. The body portion 12 includes a display unit 14 configured to display information. The display unit 14 includes a display screen 16 on which a touch panel 18 is mounted. The display screen 16 displays image information such as characters and figures. The image information includes a keyboard display, for example.

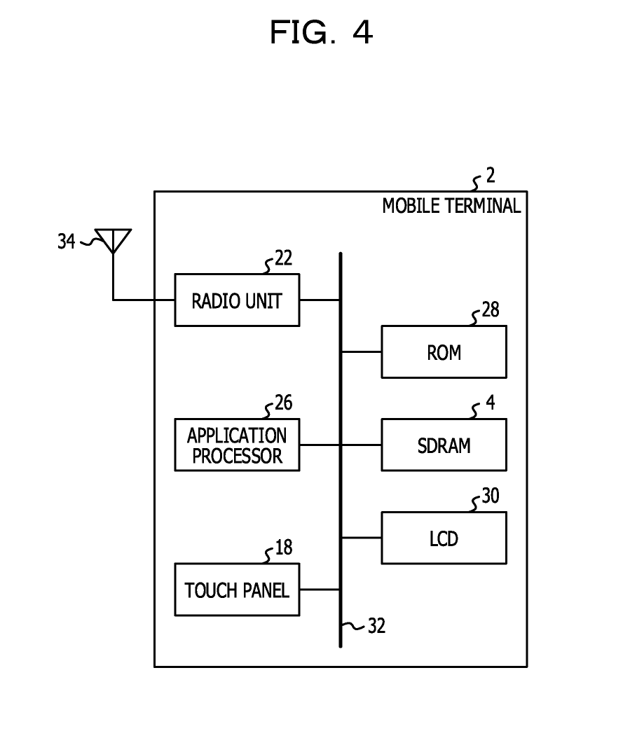

FIG. 4 illustrates example hardware of the mobile terminal 2. The mobile terminal 2 includes an SDRAM 4, a touch panel 18, a radio unit 22, an application processor (hereinafter simply referred to as “a processor”) 26, a read-only memory (ROM) 28, and a liquid crystal display (LCD) 30, which are coupled with one another by a bus 32.

The radio unit 22 includes an antenna 34 and is controlled by a built-in processor of the radio unit 22 so as to transmit and receive a radio signal. The processing performed by the radio unit 22 includes processing of creating a data signal and a radio signal including modulation of an audio signal or reproduction processing of modulating a data signal or an audio signal from a radio signal received from a base station.

The SDRAM 4 is an example DRAM of the present disclosure. The SDRAM 4 configures a work area for information processing.

The processor 26 executes an operating system (OS), a firmware program, and an application program which are stored in the ROM 28 to perform information processing. The application program includes a power control program of the present disclosure.

The ROM 28 stores various kinds of application programs including an OS, a firmware program, and a power control program. As the ROM 28, various kinds of recording media such as a hard disk and a semiconductor storage element are used.

The LCD 30 is an example of the display unit 14 and displays visual information such as input information of the information processing, processing information, and processing result information.

The touch panel 18 is used to input information by a touch. As one example, keyboard information is inputted by touching a keyboard displayed on the display screen 16 of the LCD 30.

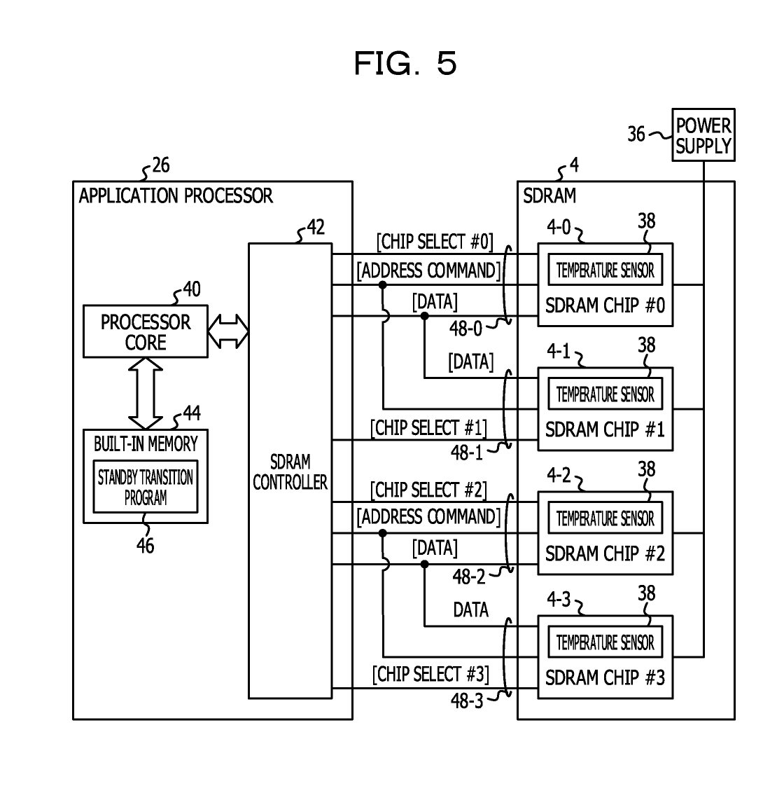

FIG. 5 illustrates an example of the processor 26 and SDRAM 4 of the mobile terminal 2.

In the mobile terminal 2, the application program is mainly operated on the processor 26. The various kinds of data including application programs to be operated on the processor 26 are stored in the SDRAM 4. The application programs which are used by a user ranges widely and stored in different regions of the SDRAM 4, in other words, the different chips 4-0, 4-1, 4-2, and 4-3. Accordingly, depending on the application programs to be used by a user, a utility status of the region on the SDRAM 4 or the temperatures of the chips 4-0, 4-1, 4-2, and 4-3 defer.

To detect such a temperature, a temperature sensor 38 is mounted in each of the chips 4-0, 4-1, 4-2, and 4-3. The temperature information obtained from each temperature sensor 38 is acquirable by issuing a command and responding to the data. The temperature information is utilized for changing a refresh rate depending on the temperature. In the present embodiment, the temperature information is utilized for standby control on the SDRAM 4, which is a power control of the present disclosure.

For example, the SDRAM 4 includes multiple chips 4-0, 4-1, 4-2, and 4-3. Each of the chips 4-0, 4-1, 4-2, and 4-3 is provided with power desired for holding data from the power unit 36.

The processor 26 is an example of the foregoing control unit 6. The processor 26 illustrated in FIG. 5 includes a processor core 40, an SDRAM controller 42, and a built-in memory 44. In the embodiment, a single processor core 40 is illustrated, but multiple processor cores 40 are possible.

When the SDRAM 40 transitions to a standby mode, the processor core 40 executes a standby transition program 46 which is in the built-in memory 44. The standby transition program 46 is an example of the power control program.

When the standby transition program 46 is executed, the SDRAM controller 42 receives an instruction from the processor core 40 and executes processing on the SDRAM 4, such as data saving based on the temperature information.

The SDRAM controller 42 and the chips 4-0, 4-1, 4-2, and 4-3 are coupled with one another by buses 48-0, 48-1, 48-2, and 48-3. These buses 48-0, 48-1, 48-2, and 48-3 are used for communications between the SDRAM controller 42 and the chips 4-0, 4-1, 4-2, and 4-3. Each of the buses 48-0, 48-1, 48-2, and 48-3 includes a chip select line, an address command line, and a data line. A chip select signal is transmitted to the chip select line. An address signal and a command signal are transmitted to the address and command lines. Also, a data signal is transmitted to the data line. In this embodiment, the data line and the address and command lines on the chip 4-1 side are branched from the chip 4-0 side. In addition, the data line and the address and command lines on the chip 4-3 side are branched from the chip 4-2 side. Accordingly, the data line and the address and command lines of the buses 48-0, 48-1, 48-2, 48-3 are simplified on the SDRAM controller 42 side.

<The Chips 4-0, 4-1, 4-2, 4-3 of the SDRAM 4>

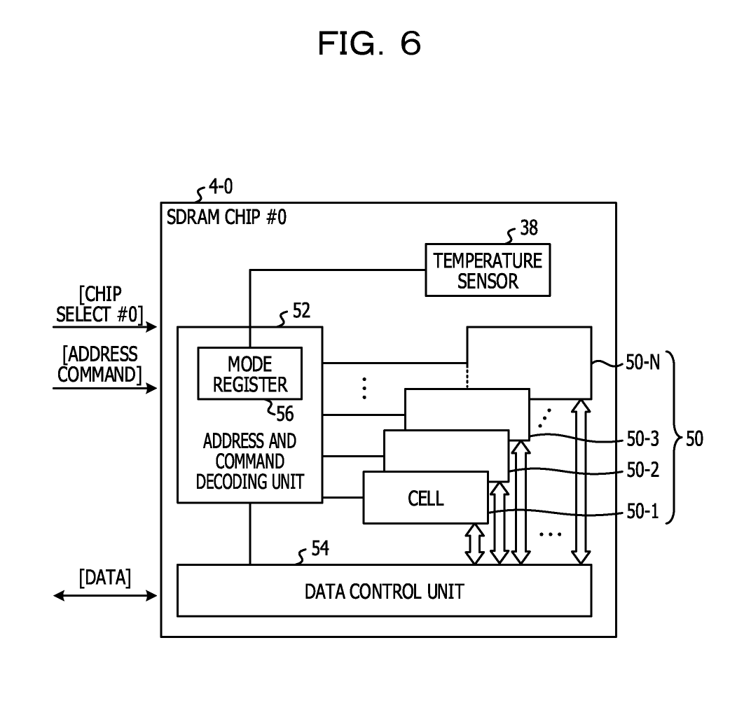

FIG. 6 illustrates an example of the chip 4-0 of the SDRAM 4. The chip 4-0 includes a memory cell 50, an address and command decoding unit 52, a data control unit 54, and a temperature sensor 38.

The memory cell 50 includes multiple cells 50-1, 50-2, 50-3, . . . , and 50-N. Each of the cells 50-1, 50-2, 50-3, . . . , and 50-N provide data storage regions. Each of the cells 50-1, 50-2, 50-3, . . . , and 50-N includes multiple capacitors and switches which are arranged in a matrix form, for example. In each of the cells 50-1, 50-2, 50-3, . . . , and 50-N, data is stored in the capacitors in a rewritable manner by the switch operation.

The address and command decoding unit 52 includes a function to decode the address and the command. The address is outputted to the memory cell 50. The command of the memory operation is outputted to the memory cell 50 and the data control unit 54. The command of the memory operation includes reading and writing of data, refresh of the memory cell 50, shutting down of power, and the like.

The address and command decoding unit 52 includes a mode register 56. The command of operating the mode register 56 includes reading and writing to the mode register 56. The temperature information of the temperature sensor 38 is stored in the mode register 56. Then the temperature data of the temperature sensor 38 in the mode register 56 is read according to the command from the processor 26 and the data is returned.

The data control unit 54 performs input and output control of the data with the memory cell 50 by the decoded address or command.

The components and functions of the chip 4-0 are same in the other chips 4-1, 4-2, and 4-3, and the description thereof is omitted.

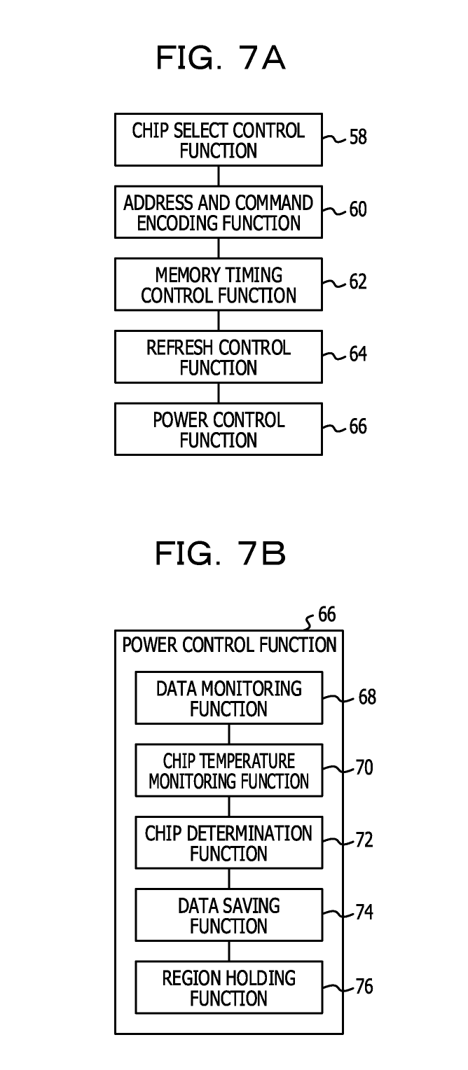

FIG. 7A illustrates functions of the processor 26. The functions achieved by the processor 26 include a chip select control function 58, an address command encoding function 60, a memory timing control function 62, a refresh control function 64, and a power control function 66.

The chip select control function 58 selects one or two or more chips, in which data 8 is read and written, from among the multiple chips 4-0, 4-1, 4-2, and 4-3. To execute this control, chip selects #0, #1, #2, and #3 are issued.

The address command encoding function 60 encodes the address or command. The issued address and command designate regions of the chips 4-0, 4-1, 4-2, and 4-3 in which the data is stored.

The memory timing control function 62 synchronizes operation timing of the SDRAM controller 42 and the SDRAM 4.

The refresh control function 64 controls a region and timing to refresh the SDRAM 4. The refresh control function 64 creates a command of refresh. For example, the command includes a power down command (deep power down (DPD)), a partial refresh command (partial array self refresh (PASR)), or a self refresh command (self refresh (SREF)).

The power control function 66 determines a chip with a low temperature based on the temperature information and saves the data in the chip with a low temperature.

FIG. 7B illustrates functions of the power control function 66. The power control function 66 includes a data monitoring function 68, a chip temperature monitoring function 70, a chip determination function 72, a data saving function 74, and a region holding function 76.

The data monitoring function 68 includes determinations of an amount of data, a storage region, and a storage capacity, which are stored in the SDRAM 4. In the data monitoring function 68, an amount of data stored in the SDRAM 4 is calculated. For example, in the determination of the storage region, any one or two or more of the chips 4-0, 4-1, 4-2, and 4-3 are selected. Also, for example, the determination of the storage capacity includes calculation of the number of chips as the storage capacity desired for storing that amount of data.

The chip temperature monitoring function 70 monitors temperatures of the chips 4-0, 4-1, 4-2, and 4-3. To monitor the temperatures, the temperature information obtained from the temperature sensors 38 of the chips 4-0, 4-1, 4-2, and 4-3 is used.

The chip determination function 72 determines a chip with a low temperature based on the temperature information of the chips 4-0, 4-1, 4-2, and 4-3. In this determination, the temperatures of the chips 4-0, 4-1, 4-2, and 4-3 are compared with one another. As a result of the comparison, a single or multiple chips with a low chip are selected.

The data saving function 74 saves and stores the data 8 in the chip with a low temperature when the SDRAM 4 is transitioned to a standby mode.

The region holding function 76 holds the data in the region of the chip in which the data to be saved is stored. For example, to hold the data in the region, refresh such as partial refresh or self refresh is used. The self refresh is an example of refresh to be performed on the entire region of the chip, and the partial refresh is an example of self refresh to be performed on a partial region of the chip.

### Comparative Example

### Standby Transition (Self Refresh) of the SDRAM 4

In a state where display or an operation is not performed, the mobile terminal 2 transitions to a standby mode to suppress current consumption. In this transition to a standby mode, the SDRAM 4 is controlled to be in a standby transition (self refresh) state. For example, this standby mode causes an operation program of the processor 26 to be temporarily stopped and transition the SDRAM 4 to the self refresh state. In this standby mode, the SDRAM 4 only performs the operation of holding the stored data, and thus power consumption may be suppressed. However, in the standby mode, it is impossible that the data is read and written.

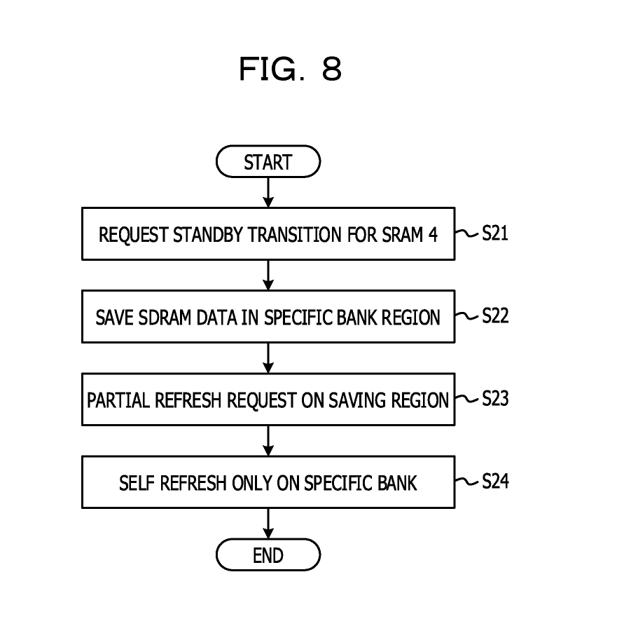

FIG. 8 illustrates a processing procedure of the standby transition processing according to the comparative embodiment. In the processing procedure, when a standby transition request for the SDRAM 4 is generated (step S21), processing of gathering regions which have to hold the data in a specific bank (BANK) region is performed (step S22). The standby transition request is caused to occur when the mobile terminal 2 has been continuously not operated for a predetermined period of time, for example. The BANK is a unit of performing partial refresh. In the processing of gathering in a specific BANK region, the SDRAM data is saved in the specified BANK region.

Since only the specific BANK region is held just after the data is saved, a partial refresh request for the SDRAM data saved region is issued from the processor 26 to the SDRAM 4 (step S23). This partial refresh request causes the self refresh to be performed only in the specific BANK region (step S24), and the SDRAM 4 transitions to the self refresh state. Then, the processing terminates.

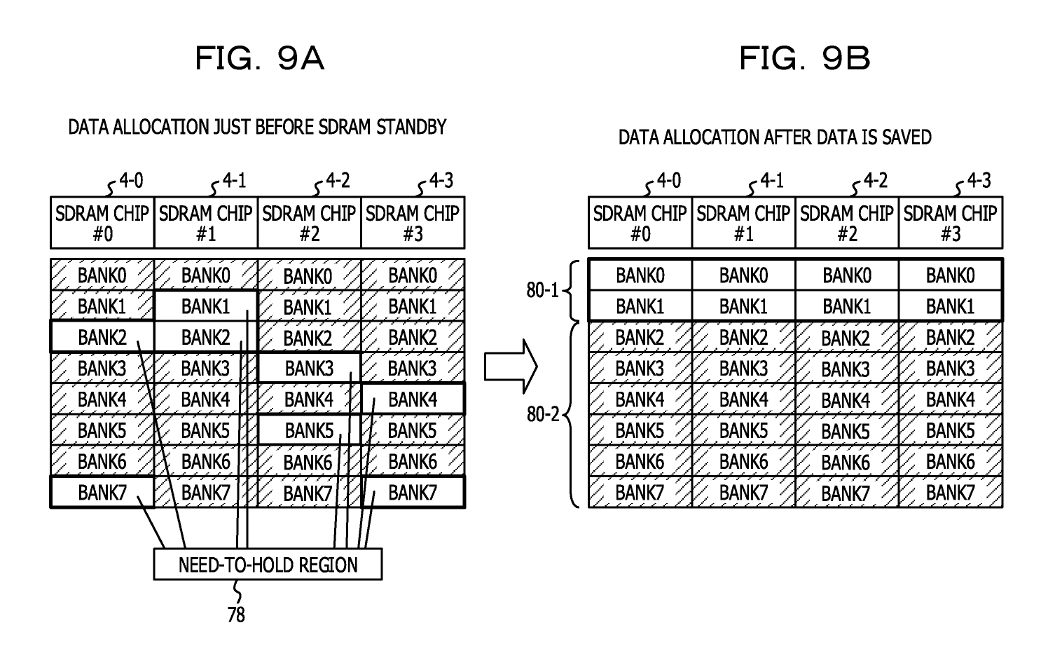

FIG. 9 illustrates data allocation before and after the standby of the SDRAM 4, in other words, data allocation before and after the partial refresh.

A in FIG. 9 illustrates data allocation just before the SDRAM standby. As one example, each of the chips 4-0, 4-1, 4-2, and 4-3 includes BANK 0, BANK 1, BANK 2, BANK 3, BANK 4, BANK 5, BANK 6, and BANK 7.

In this example, data is stored in the BANK 2 and BANK 7 of the chip 4-0, the BANK 1 and BANK 2 of the chip 4-1, the BANK 3 and BANK 5 of the chip 4-2, and the BANK 4 and BANK 7 of the chip 4-3. These BANKs storing the data is a need-to-hold region 78.

B in FIG. 9 illustrates data allocation after the SDRAM standby, in other words, data allocation after the data is saved.

The data saving is executed by the standby request for the SDRAM 4. As a result, the data is saved in the BANK 0 and BANK 1 of the chips 4-0, 4-1, 4-2, and 4-3. In this example, the BANK 0 and BANK 1 of each chip is a holding region 80-1. In contrast, the BANK 2, BANK 3, BANK 4, BANK 5, BANK 6, and BANK 7 are a non-holding region 80-2. The self refresh is executed only on the BANK 0 and BANK 1 which are data saving BANKs.

In the self refresh utilizing the partial refresh, the data is not held in the BANK 2, BANK 3, BANK 4, BANK 5, BANK 6, and BANK 7. Thus, as compared with the case where all the data is held in all the BANKs, power is reducible by approximately one fourth. However, the self refresh is executed regardless of the temperatures of the chips 4-0, 4-1, 4-2, and 4-3. For example, when the temperatures of the chips 4-0, 4-1, and 4-2 are high, the data is held in the chips 4-0, 4-1, and 4-2 with a high temperature. In this case, power consumption is not reduced but increased in the chips 4-0, 4-1, and 4-2 with a high temperature.

<Power Saving Processing on the SDRAM 4>

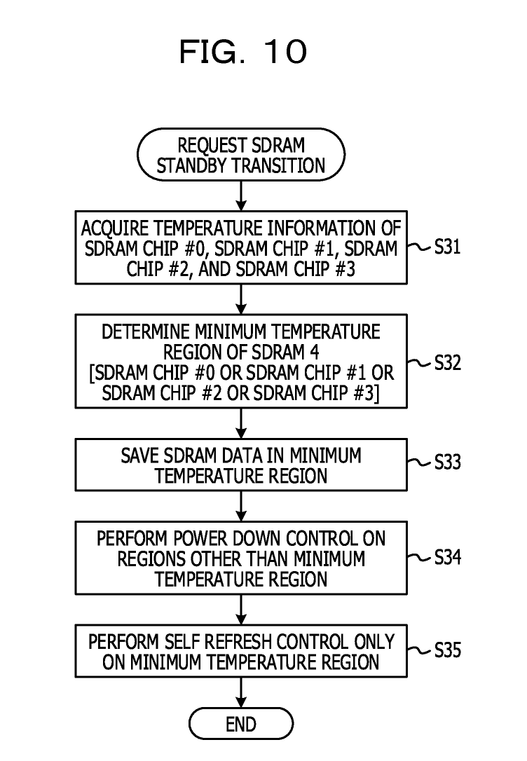

FIG. 10 illustrates an example processing procedure of power saving processing performed on the SDRAM 4. In this processing procedure, the SDRAM standby transition request causes the temperature information of the chips 4-0, 4-1, 4-2, and 4-3 to be read (step S31). A minimum temperature region of the SDRAM 4 is determined from the temperature information (step S32). In this case, a chip with a low temperature is determined from the temperature information of the chips 4-0, 4-1, 4-2, and 4-3. In the determination of a chip with a low temperature, at least one chip with a low temperature is selected among the chips. The number of chips to be selected may be two or more according to an amount of data to be saved.

Based on the chip selection result, the SDRAM data is saved in the minimum temperature region (step S33). In other words, the data is saved in a chip with a low temperature.

After the data is saved, power down control is performed on regions other than the minimum temperature region (step S34). The self refresh control is executed only on the minimum temperature region (step S35) and the processing terminates.

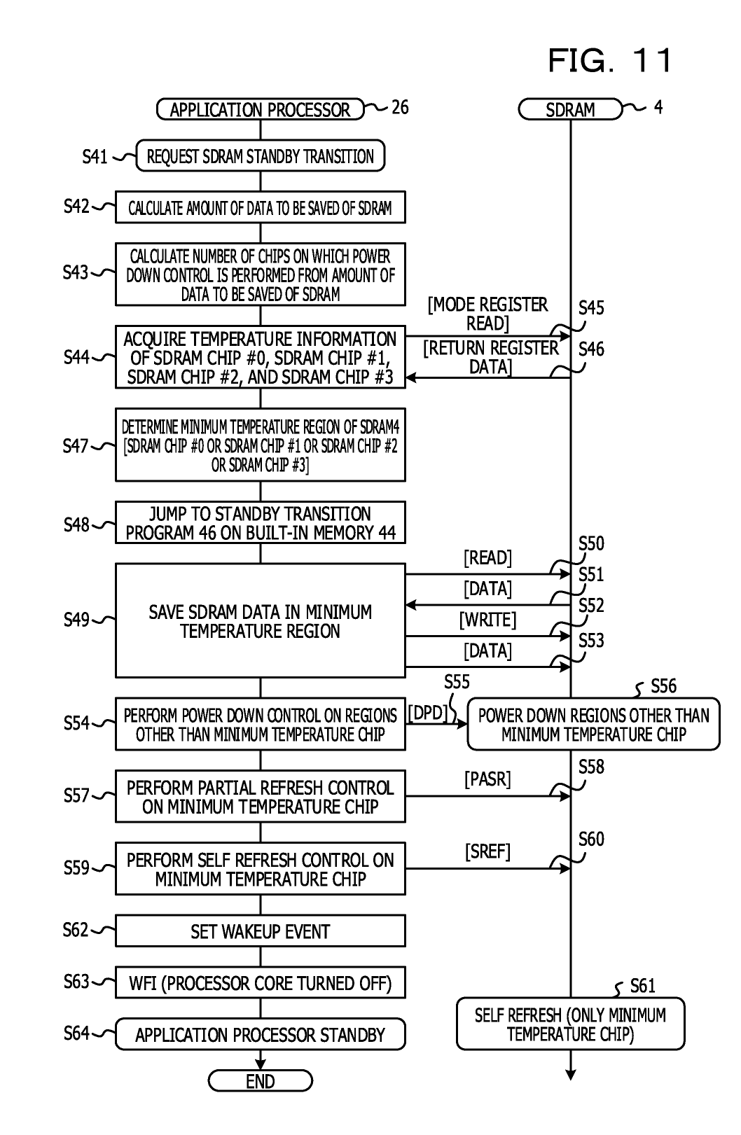

FIG. 11 illustrates a detailed example of a processing sequence of power control of the SDRAM. The processing sequence is an example of the power control method and power control program of this disclosure.

In the processor 26, by being prompted by the standby transition request for the SDRAM 4 (step S41), an amount of data to be saved of the SDRAM 4 is calculated (step S42). This amount of data to be saved is an amount of data stored in the SDRAM 4 at the time of the standby transition request.

In the embodiment, the number of chips controlling the power down control is calculated based on the amount of data to be saved (step S43). For example, the number of chips is the number of chips which is obtained by calculating the number of chips capable of storing the amount of data to be saved and then subtracting this number of chips from the total number of chips.

The temperature information of the chips 4-0, 4-1, 4-2, and 4-3 is acquired (step S44). In this processing, the processor 26 transmits a mode register read command to the SDRAM 4 (step S45) and receives a register data from the SDRAM 4 (step S46). This register data includes the temperature information stored in the mode register 56.

In the processor 26, a minimum temperature region of the SDRAM 4 is determined from the acquired temperature information (step S47). For example, a minimum temperature region is determined from the chips 4-0, 4-1, 4-2, and 4-3.

The processing of the embodiment jumps to the standby transition program 46 of the built-in memory 44 (step S48). Accordingly, the standby transition program 46 is executed.

With this processing, the processor 26 saves the SDRAM data to be saved in the minimum temperature region (step S49). In this processing, a data read command is transmitted from the processor 26 (step S50), the saved data is received (step S51), a write command is transmitted (step S52), and the saved data is transmitted (step S53). Accordingly, the saved data is stored in the minimum temperature region.

The processor 26 performs power down control on chips other than the minimum temperature chip storing the saved data (step S54). In this control, a power down command DPD is transmitted from the processor 26 to the SDRAM 4 (step S55). In the SDRAM 4, the regions other than the minimum temperature chip are shut down (step S56).

After the power down control, the processor 26 executes the partial refresh control on the minimum temperature chip (step S57). In this case, a command PASR is transmitted to the minimum temperature chip of the SDRAM 4 from the processor 26 (step S58), and the partial refresh is executed.

After this partial refresh control, the processor 26 performs self refresh control (step S59) on the minimum temperature region storing the saved data. In this case, a command SREF is transmitted to the minimum temperature region from the processor 26 (step S60) and the self refresh is executed.

Through such processing, the self refresh is performed only on the minimum temperature region in the SDRAM 4 (step S61). The processing on the SDRAM 4 is terminated.

In the processor 26, a wakeup event is set (step S62) and wait for interrupt (WFI) processing is executed (step S63). The wakeup event is processing to cause the transition from the standby mode to an active state. The WFI processing is an instruction to wait for an interruption using a WFI command, in which power of the processor core 40 is turned off by the WFI processing. With this processing, the processor 26 stands by (step S64) and the processing on the processor 26 is terminated.

<Chip Determination Processing>

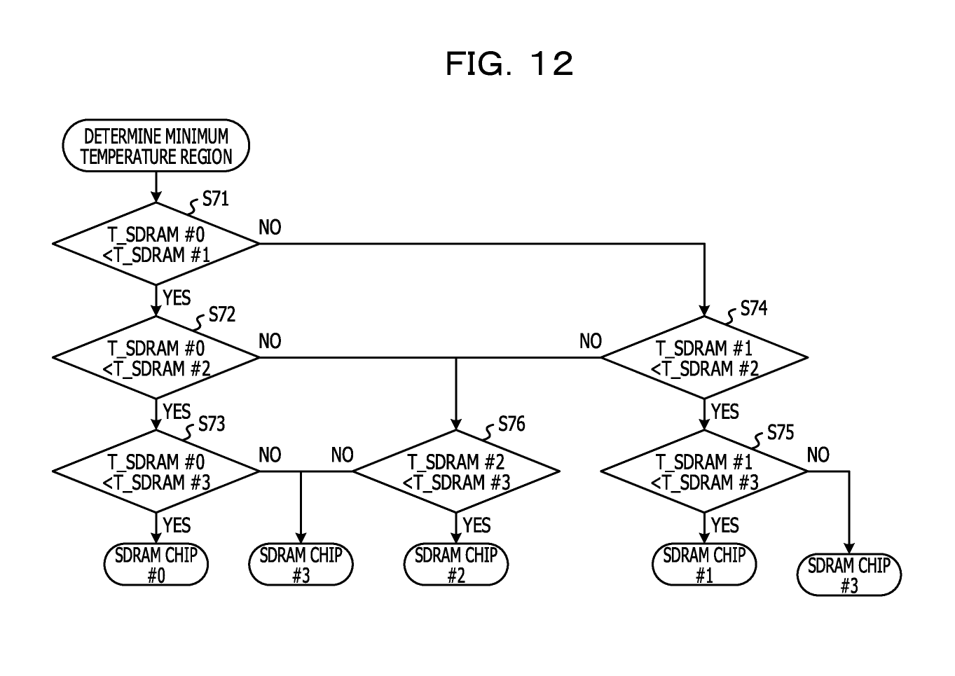

FIG. 12 illustrates an example processing procedure of chip determination processing. This processing procedure is a sub-routine of the minimum temperature region determination processing (step S47) of the processing sequence in FIG. 11.

In this processing procedure, pieces of the temperature information T_SDRAM #0, T_SDRAM #1, T_SDRAM #2, and T_SDRAM #3 of the chips 4-0, 4-1, 4-2, and 4-3, which are acquired from the SDRAM 4 are individually compared with one another to determine a minimum temperature chip.

Firstly, it is determined if T_SDRAM #0<T_SDRAM #1 (step S71). When T_SDRAM #0<T_SDRAM #1 (YES at step S71), it is determined if T_SDRAM #0<T_SDRAM #2 (step S72). When T_SDRAM #0<T_SDRAM #2 (YES at step S72), it is determined if T_SDRAM #0<T_SDRAM #3 (step S73). When T_SDRAM #0<T_SDRAM #3 (YES at step S73), it is identified that T_SDRAM #0 is the lowest and the chip 4-0 is the minimum temperature chip. Also, when T_SDRAM #0<T_SDRAM #3 is not satisfied (NO at step S73), it is identified that T_SDRAM #3 is the lowest and the chip 4-3 is the minimum temperature chip.

At step S71, when T_SDRAM #0<T_SDRAM #1 is not satisfied (NO at step S71), it is determined if T_SDRAM #1<T_SDRAM #2 (step S74). When T_SDRAM #1<T_SDRAM #2 (YES at step S74), it is determined if T_SDRAM #1<T_SDRAM #3 (step S75). When T_SDRAM #1<T_SDRAM #3 (YES at step S75), it is identified that T_SDRAM #1 is the lowest and the chip 4-1 is the minimum temperature chip. Also, if T_SDRAM #1<T_SDRAM #3 is not satisfied (NO at step S75), it is identified that T_SDRAM #3 is the lowest and the chip 4-3 is the minimum temperature chip.

At step S72, when T_SDRAM #0<T_SDRAM #2 is not satisfied (NO at step S72), or at step S74 when T_SDRAM #1<T_SDRAM #2 is not satisfied (NO at step S74), it is determined that T_SDRAM #2<T_SDRAM #3 (step S76). When T_SDRAM #2<T_SDRAM #3 (YES at step S76), it is identified that T_SDRAM #2 is the lowest and the chip 4-2 is the minimum temperature chip. Also, when T_SDRAM #2<T_SDRAM #3 is not satisfied (NO at step S76), it is identified that T_SDRAM #3 is the lowest and the chip 4-3 is the lowest temperature chip.

With the above processing, it is possible that the minimum temperature chip is determined and the minimum temperature region which is a storage destination of the saved data is specified.

In this case, to determine a chip with a second lowest temperature after the multiple minimum temperature chips, second determination processing is performed on the temperature information of the chips other than the minimum temperature chips determined by the first determination processing, so that a minimum temperature chip is determined.

<Data Saving>

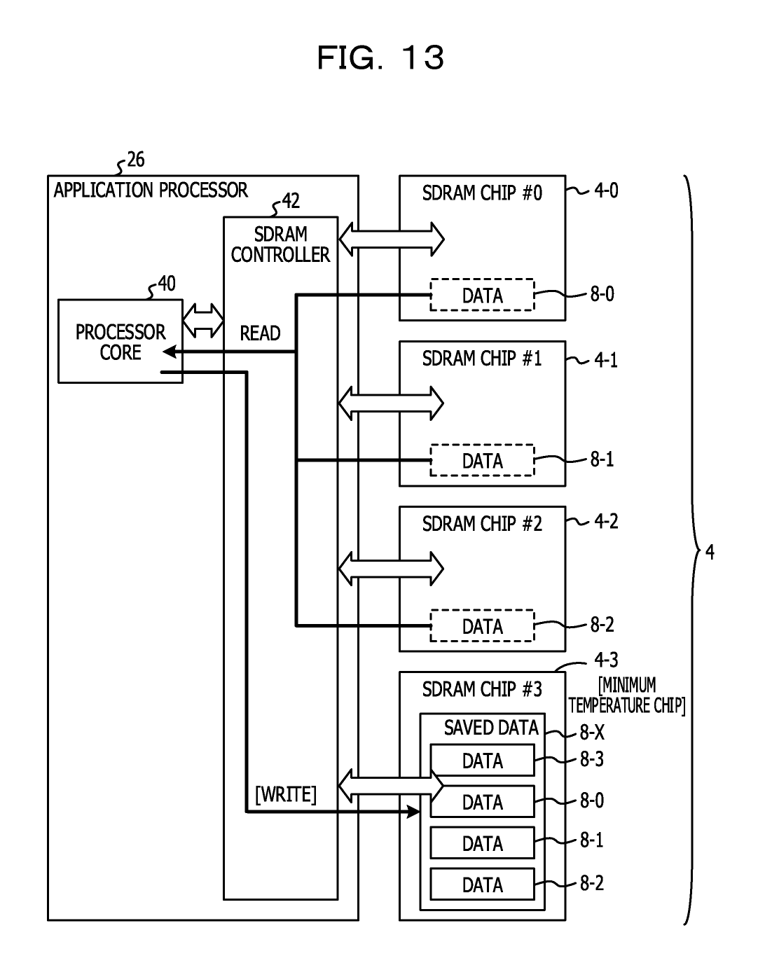

FIG. 13 illustrates an example of data saving in the SDRAM standby. As an example, the chip 4-3 is the minimum temperature chip in this data saving.

The processor 26 acquires the temperature information of the chips 4-0, 4-1, 4-2, and 4-3 according to the already mentioned standby transition processing of the SDRAM 4 in response to the standby transition request. The chip with the lowest temperature is determined from the temperature information and data is saved in the chip with the minimum temperature chip. In this example, the data saving is performed on the chip 4-3 which is the minimum temperature chip.

In this data saving, the processing of reading and writing the data is performed. In the reading processing, pieces of data 8-0, 8-1, and 8-2 of the chips 4-0, 4-1, and 4-2 are read to the processor core 40 through the SDRAM controller 42. In the writing processing, the pieces of data 8-0, 8-1, and 8-2 are transmitted to the chip 4-3 through the SDRAM controller 42 from the processor core 40 and stored in this chip 4-3. In other words, saving processing of the data 8-0, 8-1, and 8-2 is performed in the chip 4-3 with a low temperature.

The chips 4-0, 4-1, and 4-2 do not have to hold the data. Accordingly, the chips 4-0, 4-1, and 4-2 are transitioned to the power down state. Then, a self refresh request is issued only to the minimum temperature chip region and the chip 4-3 is transitioned to the self refresh sate.

<Data Allocation Before and after the Standby>

(1) In the Case of the Amount of Data to be Saved the Number of BANKs in One Chip

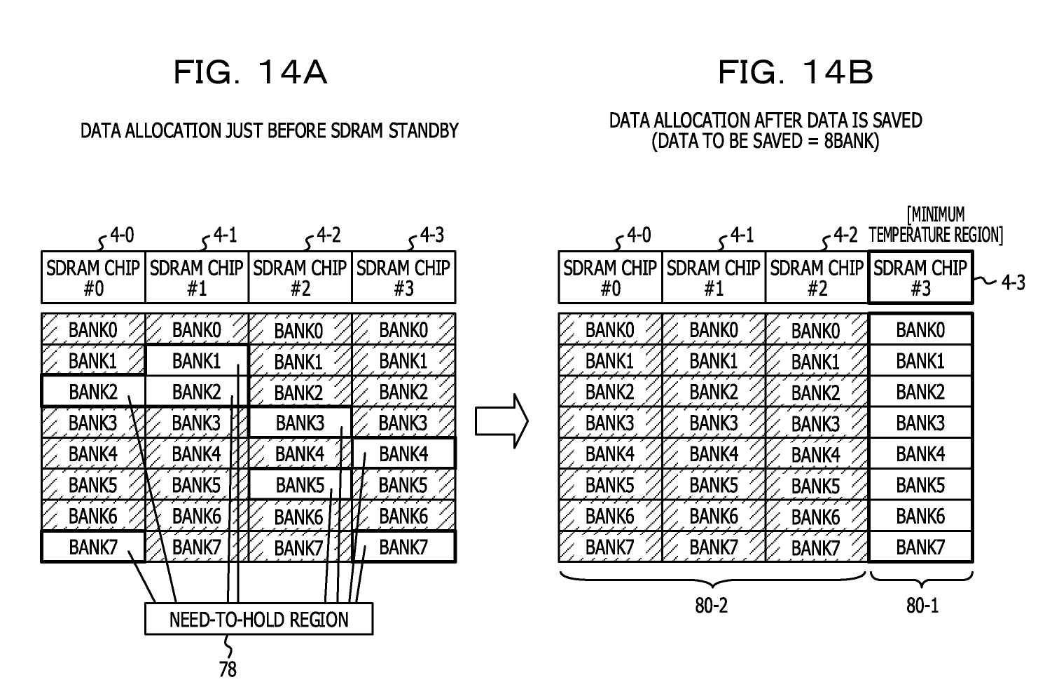

A in FIG. 14 illustrates an example data allocation just before the SDRAM standby. As an example, the number of BANKs of the chips 4-0, 4-1, 4-2, and 4-3 is 8. Accordingly, each of the chips 4-0, 4-1, 4-2, and 4-3 has BANK 0, BANK 1, BANK 2, BANK 3, BANK 4, BANK 5, BANK 6, and BANK 7 as regions to store data.

In this example, data is stored in the BANK 2 and BANK 7 of the chip 4-0, the BANK 1 and BANK 2 of chip 4-1, the BANK 3 and BANK 5 of the chip 4-2, and the BANK 4 and BANK 7 of the chip 4-3. These BANKs are a need-to-hold region 78 which has to hold the data.

B in FIG. 14 illustrates an example data allocation after the data saving. In this example, since the minimum temperature region is in the chip 4-3, the data is saved in the chip 4-3. The number of BANKs of the need-to-hold region 78 is 8, which is same as the number of BANKs of the chip 4-3. In other words, the amount of data to be saved is the number of BANKs in one chip.

Accordingly, the pieces of the data in the BANKs of the chips 4-0, 4-1, and 4-2 are saved in the chip 4-3. In the data allocation illustrated by B in FIG. 14, the BANKs of the chip 4-3 are a holding region 80-1 and the BANKs of the chips 4-0, 4-1, and 4-2 are a non-holding region 80-2.

In this saving state, the self refresh is performed on the BANK 0, BANK 1, BANK 2, BANK 3, BANK 4, BANK 5, BANK 6, and BANK 7 of the chip 4-3.

As described above, since the saved data 8-X is held in the chip 4-3 with a low temperature, the standby power is suppressed. In this example, the holding region 80-1 whose capacity is same as that of the above mentioned comparative embodiment is held only in one chip 4-3, the power is reducible by about at least one fourth. This reduced power is added to the reduced power for a temperature difference between the temperatures of the holding region 80-1, which is a saving region and the non-holding region 80-2, so that a larger power reduction is achievable as compared with the comparative embodiment.

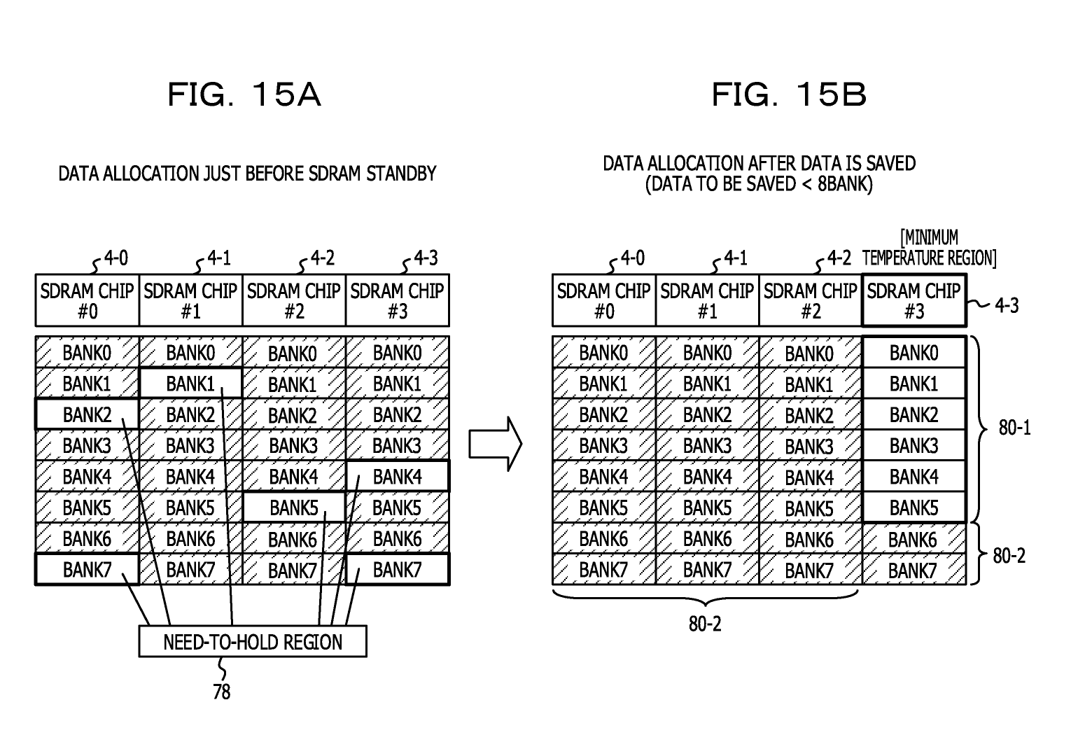

A in FIG. 15 illustrates another data allocation just before the SDRAM standby. In the example, the data is stored in the BANK 2 and BANK 7 of the chip 4-0, the BANK 1 of the chip 4-1, the BANK 5 of the chip 4-2, and the BANK 4 and BANK 7 of the chip 4-3. The number of BANKs of the need-to-hold region 78 is 6, which is less than the number of BANKs in one chip. In other words, the amount of data to be saved is smaller than the number of BANKs in one chip.

B in FIG. 15 illustrates an example data allocation after the data saving. In this example, the data saving is performed on the chip 4-3 which is the minimum temperature region. However, the number of BANKs of the need-to-hold region 78 is 6, and the BANK 0, BANK 1, BANK 2, BANK 3, BANK 4, and BANK 5 are used for data saving according to the number of data saving, which is 6. In the data allocation illustrated in B in FIG. 15, the BANK 0, BANK 1, BANK 2, BANK 3, BANK 4, and BANK 5 of the chip 4-3 are a data holding region 80-1. Also, the BANKs of the chips 4-0, 4-1, and 4-2, and the BANK 6 and BANK 7 of the chip 4-3 are a data non-holding region 80-2. Then, the partial refresh is executed on the BANK 0, BANK 1, BANK 2, BANK 3, BANK 4, and BANK 5 of the chip 4-3.

In this manner, as similar to the previous case, since the saved data 8-X is held in the chip 4-3 with a low temperature, the standby power is suppressed.

(2) In the Case that the Amount of Data to be Saved>the Number of BANKs in One Chip

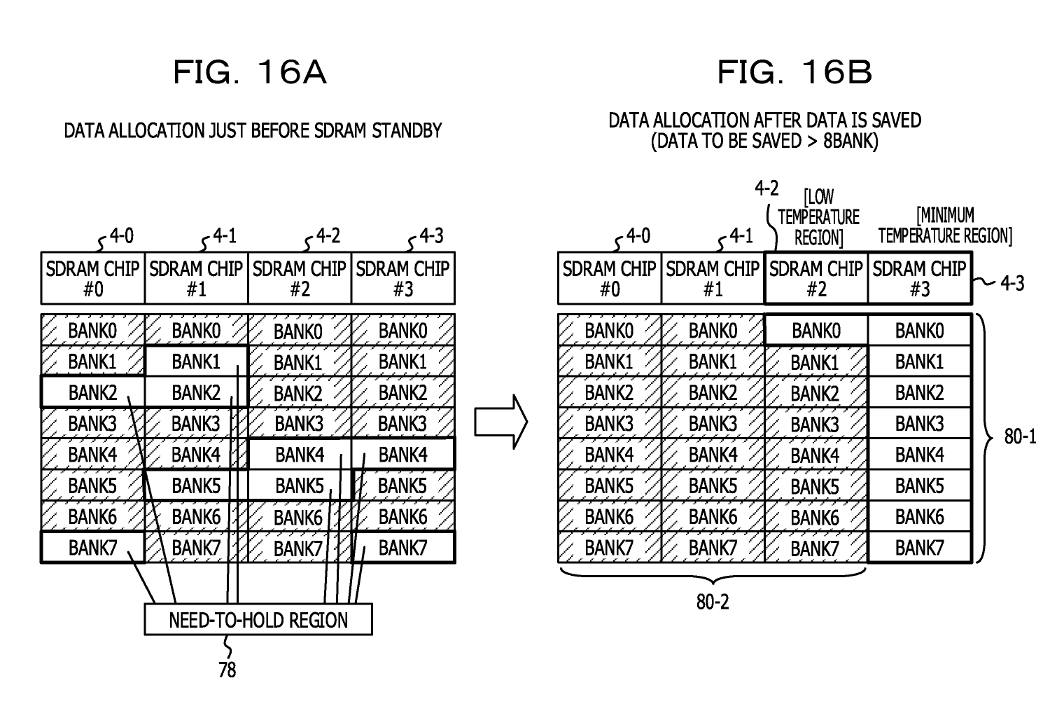

A in FIG. 16 illustrates another example data allocation just before the SDRAM standby. In this example, the data is stored in the BANK 2 and BANK 7 of the chip 4-0, the BANK 1, BANK 2, and BANK 5 of the chip 4-1, the BANK 4 and BANK 5 of the chip 4-2, and the BANK 4 and BANK 7 of the chip 4-3. The number of the BANKs in the need-to-hold region 78 is 9 and the number is bigger, only by 1, than the number of BANKs in one chip. In other words, the amount of data to be saved is larger than the number of BANKs in one chip.

B in FIG. 16 illustrates another example data allocation after the data is saved. In the example, the data saving is performed in the chip 4-2 which is a low temperature region besides the chip 4-3 which is the minimum temperature region. In other words, since the number of BANKs in the need-to-hold region 78 is 9, the BANKs of the chip 4-3, which are the minimum temperature regions, are preferentially used for the data saving. In addition to this, the BANK 0 of the chip 4-2 is used as the minimum temperature region for the data saving. In the data allocation illustrated in B in FIG. 16, the BANKs of the chip 4-3 and the BANK 0 of the chip 4-2 are the holding region 80-1. Then, the BANKs of the chips 4-0 and 4-1, the BANK 1, BANK 2, BANK 3, BANK 4, BANK 5, BANK 6, and BANK 7 of the chip 4-2 are the non-holding region 80-2.

Accordingly, the self refresh is executed on the BANK 0, BANK 1, BANK 2, BANK 3, BANK 4, BANK 5, BANK 6, and BANK 7 of the chip 4-3. The partial refresh is executed on the BANK 0 of the chip 4-2. As a result, the standby power is suppressed.

<Correlation Between the Standby Power and Temperature of the SDRAM 4>

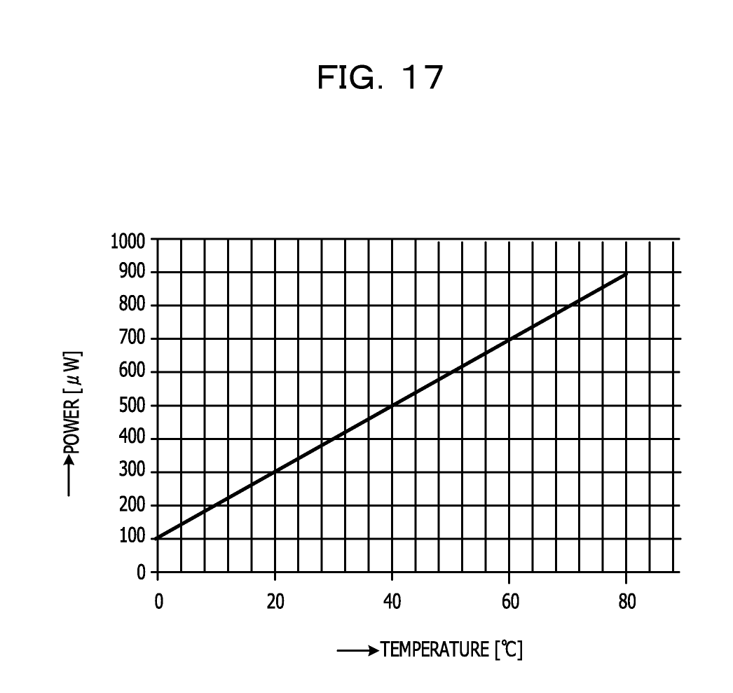

FIG. 17 illustrates a correlation between the standby power and temperature of the SDRAM. In FIG. 17, the vertical axis expresses power [unit: μW] and the horizontal axis expresses a temperature [unit: ° C.].

The standby power of the SDRAM increases in proportion to the temperature. In other words, even when a difference is generated in an inclination in some degree due to a difference in the manufacturing process, such an increasing tendency is identified that the power almost depends on the temperature and the standby power depends on the temperature.

Based on the correlation, it is to be said that when a temperature of the chip holding the data is low, the standby power decreases, and when a temperature thereof is high, the standby power increases. When the amount of data is same, a chip with a lower temperature consumes lower standby power for holding data, which is advantageous in saving power.

### Effects of the Second Embodiment

In the second embodiment, the following effects are obtainable in addition to the effect obtained in the first embodiment.

(1) A single or multiple chips with a low temperature are determined from the chips 4-0, 4-1, 4-2, and 4-3, and the data is saved in the determined chip from another chip and the region thereof is held, so that the standby power is suppressed and the power of the SDRAM 4 is saved. Moreover, since the data is saved just before the SDRAM 4 is transitioned to the standby mode, the SDRAM 4 is usable until just before being transitioned to the standby mode and the utilization of the stored data is not disturbed.

(2) Even when the chips 4-0, 4-1, 4-2, and 4-3 of the SDRAM 4 are miniaturized and impact of temperature increases, the data is saved in a single chip or multiple chips with a low temperature, so that the power consumption during standby may be suppressed.

(3) With the suppression of the power consumption, it is possible that the power of the mobile terminal 2 is saved and the life of battery is prolonged.

(4) Since the power down control is performed on the side of the chip with a high temperature which does not have held the data, the power during the standby of the SDRAM 4 is further suppressed together with the effect of power down control.

(5) The temperature information indicating the internal temperatures of the chips 4-0, 4-1, 4-2, and 4-3 is acquired from the temperature sensors 38, if there are existing sensors in the chips 4-0, 4-1, 4-2, and 4-3, they may be used as the temperature sensors 38. If there are no existing sensors in the chips 4-0, 4-1, 4-2, and 4-3, the temperature sensors 38 may be provided.

### Other Embodiment

(1) As for Calculation of the Number of Chips or BANKs

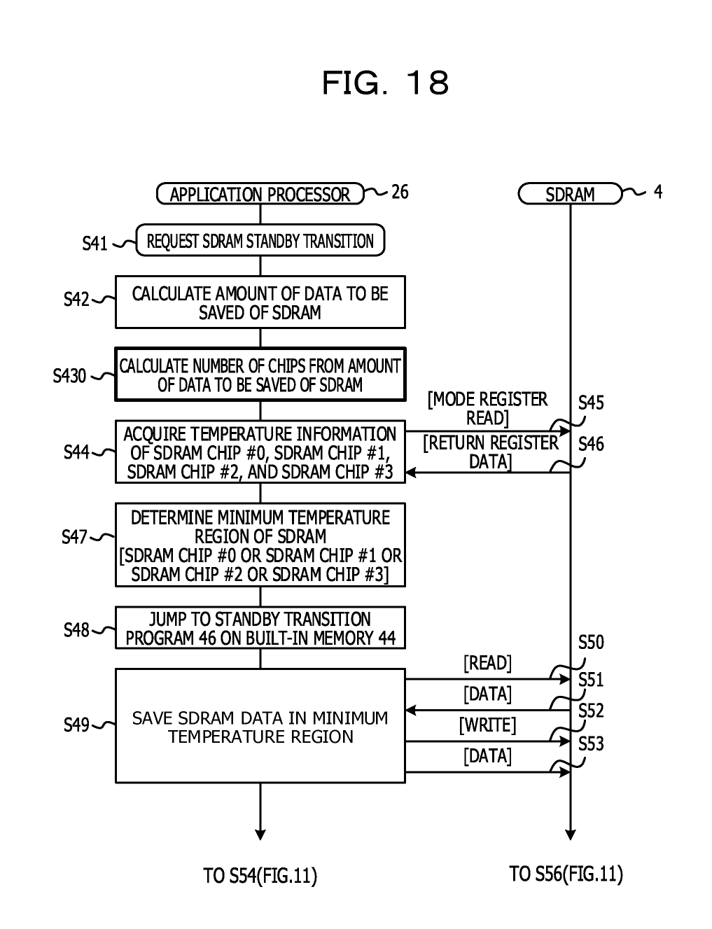

In the second embodiment, as illustrated in step S43 in FIG. 11, the processing of calculating the number of chips on which the power down control is performed based on the amount of data of the SDRAM to be saved. As described in step S430 in FIG. 18, this calculation of the number of chips may calculate the number of chips in which an amount of data to be saved is stored. The chip on which the power down control is performed or the chip in a saving destination may be identified from the number of chips. Also, in place of the number of chips, the number of BANKs may be calculated. In FIG. 18, same reference numerals are given to denote portions same as those in FIG. 11.

(2) As for the Contents of the Standby Transition Program 46 and Jumping Timing

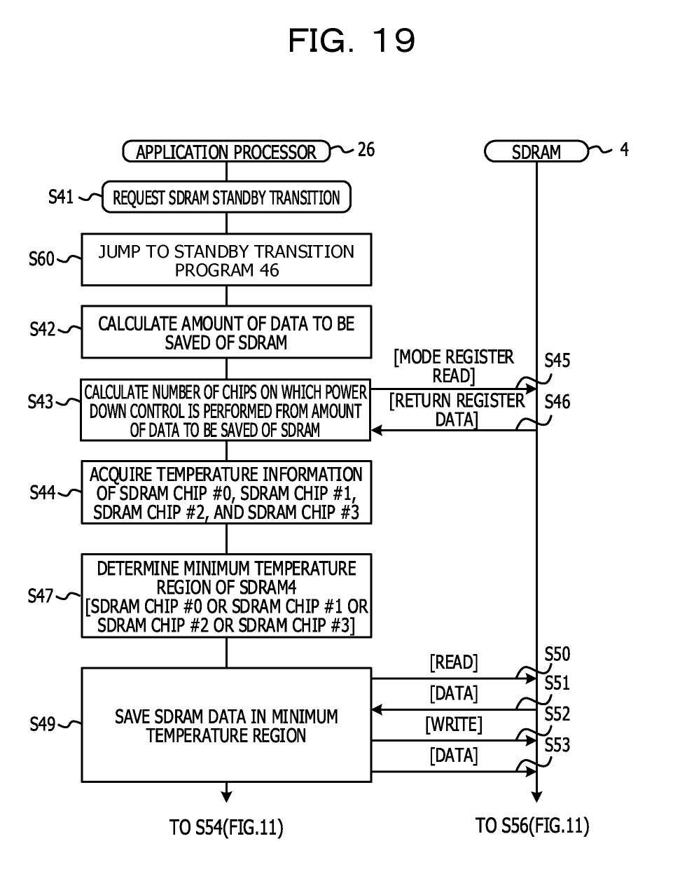

In the second embodiment, as illustrated in FIG. 11, after the SDRAM standby transition request (step S41), the processing jumps to the standby transition program 46 in the built-in memory 44 after steps S42, S43, S44, . . . , and S47 (step S48). In other words, in the above embodiment, the processes of steps S42, S43, S44, . . . , and S47 are executed by the programs other than the standby transition program 46. In place of this, the processing programs of steps S42, S43, S44, . . . , and S47 may be included in the standby transition program 46. FIG. 19 illustrates a processing procedure using the standby transition program 46 whose contents are changed as mentioned above.

In this processing procedure, after the SDRAM standby transition request (step S41), the processor 26 jumps to the standby transition program 46 (step S60). The standby transition program 46 is executed, so that the already-mentioned calculation of the amount of data to be saved of the SDRAM is performed (step S42). After executing steps S43, S44, and S47, the processing of saving data of the SDRAM into the minimum temperature region may be performed (step S49). In FIG. 19, same reference numerals are given to denote portions same as those in FIG. 11.

(3) As for the Screen Display During Standby of the Mobile Terminal 2

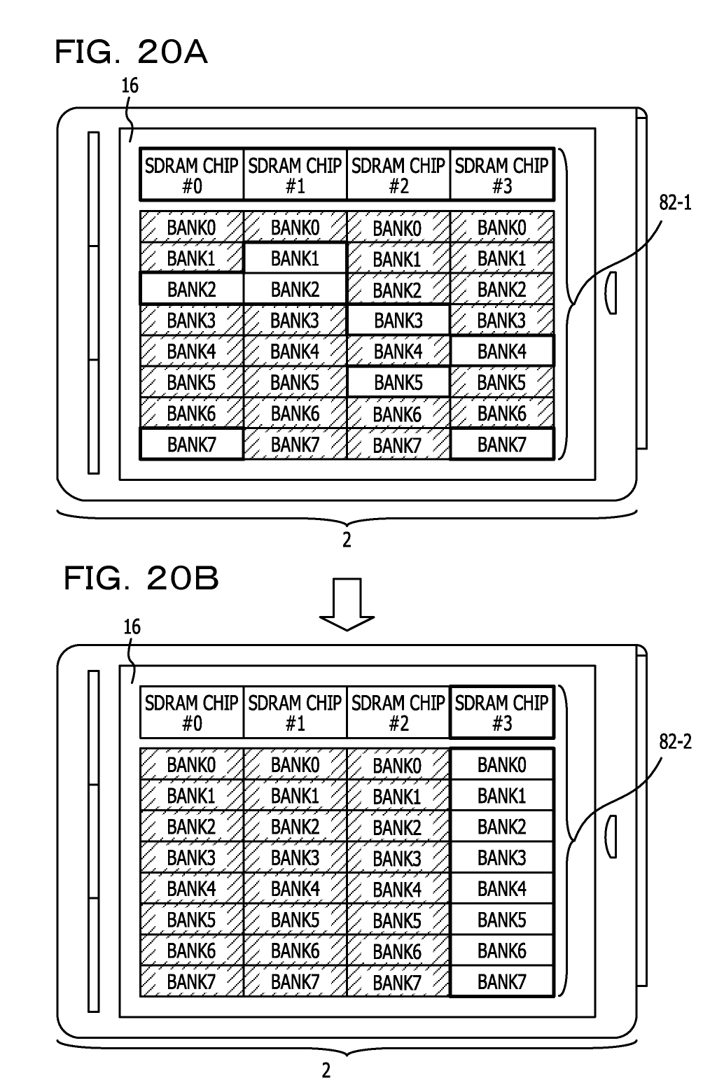

As illustrated in A in FIG. 20, the data allocation 82-1 before the SDRAM standby is displayed on the display screen 16 of the mobile terminal 2. Also, as illustrated in B in FIG. 20, the data allocation 82-2 after the SDRAM standby may be displayed. Accordingly, the contents before and after the SDRAM standby may be visually checked.

(4) In the above-described embodiment, the mobile terminal 2 is described as an example. However, the embodiment may include electronic devices with a DRAM involving the standby processing, such as smartphones, mobile telephones, tablet terminals, mobile PCs, desktop PCs, electronic still cameras, and electronic game machines, for example.

(5) In the above-described embodiment, the SDRAM 4 which is configured with the four chips 4-0, 4-1, 4-2, and 4-3 is described as an example. However, the SDRAM 4 may include more than 4 chips. The number of BANKs may exceed 8 or less than 8. When the number of chips increases, it is predictable that an amount of data becomes abundant and the temperature impact becomes larger. Accordingly, when the number of chips increases, it is possible that the power is further saved by using the above-described embodiment.

(6) In the above-described embodiment, the temperature information of the chips 4-0, 4-1, 4-2, and 4-3 is obtained from the temperature sensors 38, but it is not limited. The temperature rises according to the frequency of using the chips 4-0, 4-1, 4-2, and 4-3 and the BANKs. In other words, in the chip whose frequency in use is low has a small amount of heat generation and a low temperature. In contrast, the chip whose frequency in use is high has a large amount of heat generation and a high temperature. Such frequency in use of the chip may be used as the temperature information. With the above configuration, the temperature sensors 38 may be omitted.

(7) In the above-described embodiment, the temperature sensor 38 is provided in each of the chips 4-0, 4-1, 4-2, and 4-3 to acquire the temperature information for each chip. However, the temperature information may be obtained from the frequency in use of each BANK and this obtained temperature information may be used as the temperature information for the chips. Only thing that has to be acquired is temperatures of divided regions.

(8) In the above-described embodiment, the data is saved in the chip with a low temperature. However, a change in a refresh rate according to the temperature information may be used together.

(9) In the above-described embodiment, when being transitioned to the standby mode, all pieces of the data are saved in the chip with a low temperature from the chip with a high temperature. However, one part of the data is discarded when the data is saved and the data after the discard may be stored and held in the chip with a low temperature. When the amount of the saved data is reduced, the standby power may be reduced without reducing the capacity of the SDRAM 4.

(10) In the above-described embodiment, the processor 26 includes the built-in memory 44 and the standby transition program 46 is included in the built-in memory 44. In place of the built-in memory 44, another RAM different from the SDRAM 4 may be provided to store the standby transition program 46 and perform data transition.

Hereinafter, regarding to embodiments including the above-described embodiments, the following amendments are further disclosed. However, the present disclosure is not limited to the amendments.

As above, the embodiments of the disclosed technology are described. The disclosed technology is not limited to the above description. Based on the technical summary claimed and disclosed in the specification, those who are in the art may make various modifications and changes. It is of course natural that the modifications and changes are included in the technical scope of the disclosed technology.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An information processing terminal having a DRAM configured with a plurality of chips, the information processing terminal comprising:
a memory; and
a processor coupled to the memory, configured to monitor a temperature of each of the plurality of chips and, when the DRAM is transitioned to a standby mode, store data in a region of a chip with a low temperature among the plurality of chips and hold the data in the region alone.

2. The information processing terminal according to claim 1, wherein the processor calculates the number of chips based on an amount of data just before the DRAM is transitioned to the standby mode and selects at least one chip from among the chips to hold the data.

3. The information processing terminal according to claim 1, wherein the processor shuts down power of a chip which does not store the data.

4. The information processing terminal according to claim 1, further comprising:
temperature sensors each provided at the respective chips to detect respective chip temperatures, wherein the processor determines at least one chip with a low temperature among the chips based on temperature information obtained from the temperature sensors.

5. A machine readable medium storing a program that, when executed by a processor, causes the processor to perform operations comprising:
monitoring a temperature of each of a plurality of chips;
when a DRAM configured with the plurality of chips is transitioned to a standby mode, storing data in a region of a chip with a low temperature among the chips, and
holding the data in the region alone.

6. The machine readable medium storing a program according to claim 5, further comprising:
calculating the number of chips based on an amount of data just before the DRAM is transitioned to a standby mode and
selecting at least one chip from among the chips to hold the data.

7. The machine readable medium storing a program according to claim 5, further comprising:
shutting down power of a chip which does not store the data.

8. The machine readable medium storing a program according to claim 5, further comprising:
determining at least one chip with a low temperature among the chips based on temperature information obtained from temperature sensors each provided at the respective chips.

9. A power control method of an information processing terminal having a DRAM configured with a plurality of chips, the method comprising:
monitoring a temperature of each of the plurality of chips;
when the DRAM is transitioned to a standby mode, storing data in a region of a chip with a low temperature among the chips; and
holding the data in the region alone.

10. The power control method according to claim 9, further comprising:
calculating the number of chips based on an amount of data just before the DRAM is transitioned to a standby mode; and
selecting at least one chip from among the chips to hold the data.

11. The power control method according to claim 9, further comprising:
shutting down power of a chip which does not store the data.

12. The power control method according to claim 9, further comprising:
determining at least one chip with a low temperature among the chips based on temperature information obtained from temperature sensors each provided at the respective chips.
